(19) United States
(12) Patent Application Publication
(10) Pub. No.: US 2026/0304760 A1
(43) Pub. Date: Oct. 1, 2026

(54) PATTERNING PROCESS AND MANUFACTURING METHOD OF GATE STRUCTURE OF MEMORY DEVICE

(71) Applicant: Winbond Electronics Corp., Taichung City (TW)

(72) Inventors: Tzu-Yun Huang, Taichung City (TW); Wen-Chieh Tsai, Taichung City (TW)

(73) Assignee: Winbond Electronics Corp., Taichung City (TW)

(21) Appl. No.: 19/455,830

(22) Filed: Jan. 22, 2026

(30) Foreign Application Priority Data
Mar. 27, 2025 (TW) 114111800

(51) Int. Cl. H10B 41/30

(52) U.S. Cl. CPC H10B 41/30

(57) ABSTRACT

Providing are a patterning process and a manufacturing method of gate structures of a memory device. The patterning process includes the following steps. A target layer is formed on a substrate. A patterned mask layer is formed on the target layer, wherein the patterned mask layer includes a first pattern and a second pattern, and the width of the first pattern is greater than the width of the second pattern. A sacrificial layer is conformally formed on the target layer. An ashing process is performed to remove the second pattern and a portion of the first pattern at least from the sidewall of the first pattern through the sacrificial layer such that the first pattern has a reduced width. An anisotropic etching process is performed to remove a portion of the sacrificial layer and a portion of the target layer. The remaining sacrificial layer and the first pattern are removed.

### CROSS-REFERENCE TO RELATED APPLICATION

This application claims the priority benefit of Taiwan application serial no. 114111800, filed on Mar. 27, 2025. The entirety of the above-mentioned patent application is hereby incorporated by reference herein and made a part of this specification.

### BACKGROUND

### Technical Field

The present invention relates to a semiconductor process, and more particularly to a patterning process and a manufacturing method of a gate structure of a memory device.

### Description of Related Art

In the current memory process, a multiple patterning process is usually used to form the gate structures in the memory cells. For example, the gate structures in the memory cells may be formed by using a self-aligned double patterning (SADP) process. In addition, by combining the SADP process with an additional lithographic process, the select gate structure with a larger size may be formed around the gate structures of the memory cells. However, as the size of the devices continues to decrease, the difficulty and cost for forming the gate structures in the above manner are greatly increased due to the resolution limitation of the lithography apparatus.

### SUMMARY

The present invention provides a patterning process, wherein after a patterned mask layer including a first pattern and a second pattern is formed by a lithographic process and an etching process, an ashing process is used to reduce the width of the first pattern and remove the second pattern.

The present invention provides a manufacturing method of a gate structure of a memory device, which uses the above patterning process to form the gate structure.

The patterning process of the present invention includes the following steps. A target layer is formed on a substrate. A patterned mask layer is formed on the target layer, wherein the patterned mask layer includes a first pattern and a second pattern, and the width of the first pattern is greater than the width of the second pattern. A sacrificial layer is conformally formed on the target layer. An ashing process is performed to remove the second pattern and a portion of the first pattern at least from the sidewall of the first pattern through the sacrificial layer such that the first pattern has a reduced width. An anisotropic etching process is performed to remove a portion of the sacrificial layer and a portion of the target layer. A remaining portion of the sacrificial layer and the first pattern are removed.

The manufacturing method of the gate structure of the memory device of the present invention comprises the following steps. A tunneling dielectric layer is formed on a substrate. A first gate material layer is formed on the tunneling dielectric layer. An inter-gate dielectric material layer is formed on the first gate material layer, wherein the inter-gate dielectric material layer has a discontinuous region. A second gate material layer is formed on the inter-gate dielectric material layer. A hardmask material layer is formed on the second gate material layer. A patterned mask layer is formed on the hardmask material layer, wherein the patterned mask layer comprises a first pattern and a plurality of second patterns, the first pattern is located above the discontinuous region, and a width of the first pattern is greater than a width of the second pattern. A sacrificial layer is conformally formed on the patterned mask layer. An ashing process is performed to remove the second pattern through the sacrificial layer and remove a portion of the first pattern at least from a sidewall of the first pattern so that the first pattern has a reduced width. An anisotropic etching process is performed to remove a portion of the sacrificial layer, a portion of the hardmask material layer, a portion of the second gate material layer, a portion of the inter-gate dielectric material layer and a portion of the first gate material layer. A remaining portion of the sacrificial layer and the first pattern removed.

Based on the above, in the patterning process and the manufacturing method of the gate structure of the memory device of the present invention, after forming a patterned mask layer including a first pattern and a second pattern with different widths, an ashing process is used to reduce the width of the first pattern and remove the second pattern so that the first pattern has a desired width. In this way, by using the first pattern as an etching mask, a target pattern with a desired width may be formed without being limited by the resolution of the lithography apparatus.

### BRIEF DESCRIPTION OF THE DRAWINGS

FIGS. 1A to 1F are schematic cross-sectional views of the patterning process according to the embodiment of the present invention.

FIGS. 2A to 2F are schematic cross-sectional views of the manufacturing method of the gate structure according to the embodiment of the present invention.

### DESCRIPTION OF THE EMBODIMENTS

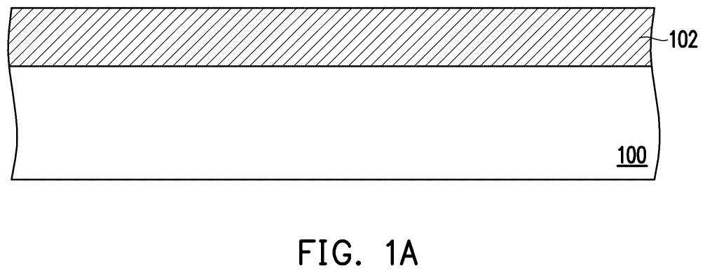

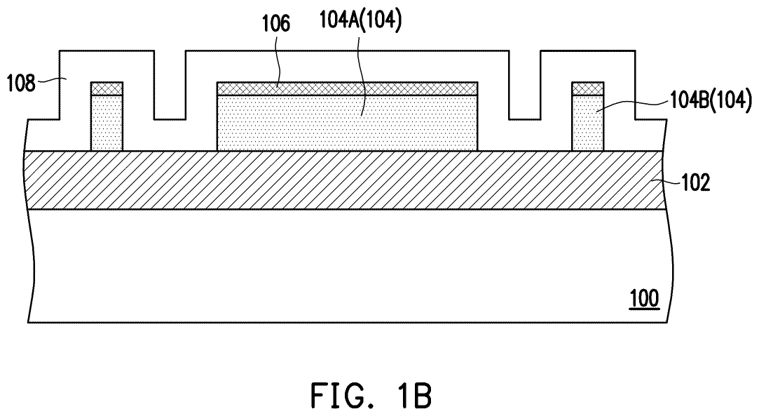

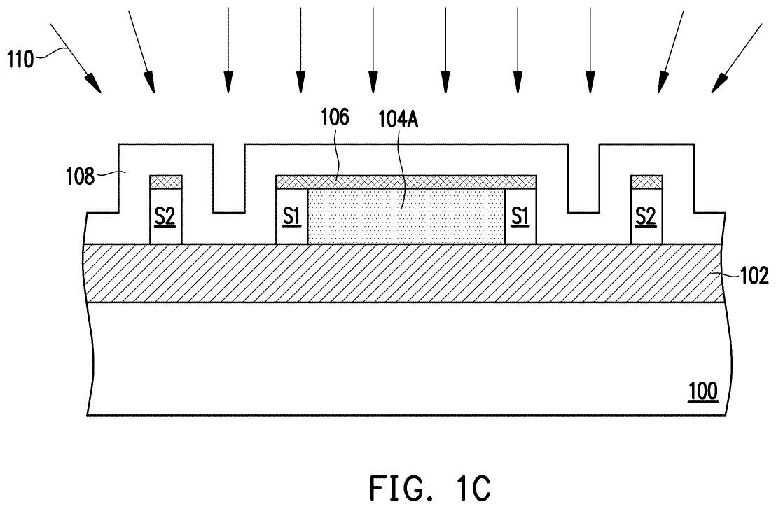

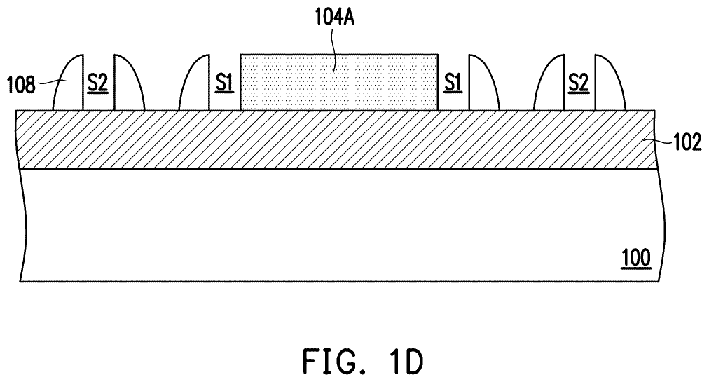

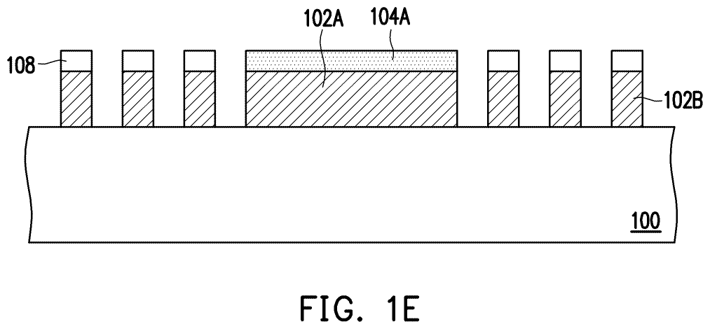

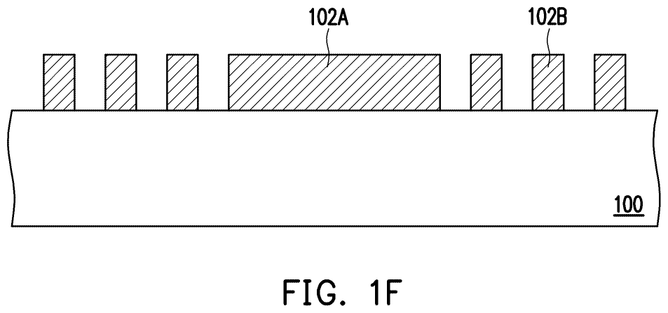

FIGS. 1A to 1F are schematic cross-sectional views of the patterning process according to the embodiment of the present invention. The patterning process of the present embodiment may pattern the target layer into including a first pattern with a larger width and a second pattern with a smaller width, and does not require an additional lithographic process to combine the multiple patterning processes. In this way, the process cost is reduced, and the patterning process may not be limited by the resolution of the lithography apparatus. This will be described in detail below.

Referring to FIG. 1A, a target layer 102 is formed on a substrate 100. In the present embodiment, there is no restriction on the substrate 100 and the target layer 102. For example, substrate 100 may be a dielectric substrate, and the target layer 102 may be a conductive layer to be patterned.

Referring to FIG. 1B, a patterned mask layer 104 is formed on the target layer 102, and a capping layer 106 is formed on the patterned mask layer 104. The patterned mask layer 104 includes a first pattern 104A having a larger width and a plurality of second patterns 104B each having a smaller width. In FIG. 1B, only two second patterns 104B are shown. However, there may be a plurality of second patterns 104B on opposite sides of the first pattern 104A. In this step, since the width of the second pattern 104B does not exceed the resolution limit of the lithography apparatus, the patterned mask layer 104 may be formed by a common lithographic process and an etching process. In the present embodiment, the material of the patterned mask layer 104 is, for example, carbon or a carbon-containing material, and the material of the capping layer 106 is, for example, oxynitride, but the present invention is not limited thereto. Depending on actual situation, in other embodiments, the capping layer 106 may be omitted.

Thereafter, a sacrificial layer 108 is conformally formed on the target layer 102. The sacrificial layer 108 covers the sidewall of the patterned mask layer 104, the capping layer 106 located on the patterned mask layer 104 and the exposed surface of the target layer 102. The material of the sacrificial layer 108 is, for example, silicon oxide, but the present invention is not limited thereto. In the present embodiment, the thickness of the sacrificial layer 108 is the same as the width of the second pattern 104B, but the present invention is not limited thereto, as long as the sacrificial layer 108 does not fill up the space between the first pattern 104A and the second pattern 104B and the space between two adjacent second patterns 104B.

Referring to FIG. 1C, an ashing process 110 is performed to remove the second patterns 104B through the sacrificial layer 108, and to remove a portion of the first pattern 104A from the sidewall of the first pattern 104A, so that the first pattern 104A has a reduced width. Spaces S1 are formed after removing the portion of the first pattern 104A, and spaces S2 are formed after removing the second patterns 104B. In the present embodiment, the material of the patterned mask layer 104 is, for example, carbon, and thus the ashing process 110 is performed using, for example, oxygen plasma.

In detail, in this step, the ashing plasma used in the ashing process 110 may pass through the sacrificial layer 108 to remove the patterned mask layer 104. Therefore, by controlling the process parameters, for example, the ashing time, of the ashing process 110, the second patterns 104B may be completely removed, and the first pattern 104A may be partially removed to reduce the width of the first pattern 104A. In other words, even if the conventional lithographic process and the etching process cannot be used directly to form the first pattern 104A with the desired width due to the resolution of the lithography apparatus, the width of the first pattern 104A may be further reduced to a desired width through the ashing process 110.

Furthermore, in the present embodiment, since the capping layer 106 is located on the patterned mask layer 104, the ashing plasma may be blocked so that the upper portion of the first pattern 104A may not be removed. In an embodiment where the capping layer 106 is not formed, the ashing plasma used in the ashing process 110 removes a portion of the first pattern 104A from the sidewall of the first pattern 104A, and also removes a portion of the first pattern 104A from the top surface of the first pattern 104A. In this case, the first pattern 104A has a reduced thickness in addition to a reduced width.

Referring to FIG. 1D, an anisotropic etching process is performed on the sacrificial layer 108 to remove a portion of the sacrificial layer 108 to form spacers formed by the sacrificial layer 108. In this step, the capping layer 106 is removed at the same time, and the spaces S1 and the spaces S2 are exposed.

Referring to FIG. 1E, by using the spacers formed by the sacrificial layer 108 and the first pattern 104A as the etching mask, an anisotropic etching process is performed to remove a portion of the target layer 102 to form a first target pattern 102A and a plurality of second target patterns 102B in the target layer 102, wherein the width of the first target pattern 102A corresponds to the width of the first pattern 104A, and the pitch between the adjacent second target patterns 102B corresponds to the width of the space S2.

In detail, in this step, the etchant of the anisotropic etching process removes a portion of the target layer 102 toward the substrate 100, and the spacers formed by the sacrificial layer 108 and the first pattern 104A are also partially removed. In addition, since an etchant having a lower etching rate (higher selectivity) for the first pattern 104A and the sacrificial layer 108 may be selected, the target layer 102 below the first pattern 104A and the sacrificial layer 108 may not be etched. Therefore, after the anisotropic etching process, some first pattern 104A still remains on the first target pattern 102A, and some sacrificial layer 108 still remains on the second target pattern 102B.

In another embodiment, there is no need to additionally form the spacers formed by the sacrificial layer 108. Instead, an anisotropic etching process is performed after the step described in FIG. 1C to remove a portion of the sacrificial layer 108, the capping layer 106, a portion of the first pattern 104A and a portion of the target layer 102 to form the first target pattern 102A and the second target patterns 102B.

In the present embodiment, the pitch between the first target pattern 102A and the second target pattern 102B corresponds to the width of the space S1. Since the space S1 is formed by removing a portion of the first pattern 104A, the amount of removing the first pattern 104A may be controlled by adjusting the time of the ashing process 110 to control the width of the space S1, thereby controlling the pitch between the first target pattern 102A and the second target pattern 102B. In addition, since the spaces S2 are formed by removing the second patterns 104B, the pitch between adjacent second target patterns 102B also corresponds to the width of the second pattern 104B, and thus the pitch between adjacent second target patterns 102B may be controlled by adjusting the width of the second pattern 104B. In addition, since the second target patterns 102B are formed by the anisotropic etching process using the spacers formed by the sacrificial layer 108 as the etching mask, the width of the second target pattern 102B may be controlled by adjusting the thickness of the sacrificial layer 108.

Referring to 1F, the first pattern 104A on the first target pattern 102A and the sacrificial layer 108 on the second target patterns 102B are removed. In this way, the target layer 102 is patterned to include a first target pattern 102A having a larger width and a plurality of second target patterns 102B having a smaller width, and the width of the first target pattern 102A and the width of the second target patterns 102B are not limited by the resolution of the lithography apparatus.

In the present embodiment, after the patterned mask layer 104 is formed by a lithographic process and an etching process, an ashing process is performed to reduce the width of the first pattern 104A and remove the second patterns 104B to form the first pattern 104A with a desired width. In this way, by using the first pattern 104A as the etching mask, the first target pattern 102A having a desired width may be formed without being limited by the resolution of the lithography apparatus. In addition, by controlling the process parameters, for example, the ashing time, of the ashing process 110, the width of the first target pattern 102A formed subsequently and the pitch between the first target pattern 102A and the second target pattern 102B may be further controlled.

In the present embodiment, the first pattern 104A and the sacrificial layer 108 are formed on the target layer 102 and in contact with the target layer 102, so the first pattern 104A and the sacrificial layer 108 may be used as the mask pattern to define the first target pattern 102A and the second target patterns 102B, but the present invention is not limited thereto. In other embodiments, depending on actual conditions, at least one additional layer may be formed between the first pattern 104A and the target layer 102 and between the sacrificial layer 108 and the target layer 102, and the same technical means as the present embodiment may be used to pattern the at least one additional layer by using the first pattern 104A and the sacrificial layer 108 as the mask, and then define the first target pattern 102A and the second target patterns 102B by using the patterned additional layer as the mask.

The patterning process of the present embodiment may be used to form various semiconductor patterns, such as the gate structure of the memory cell and the select gate structure with different widths in the memory device. This will be described in detail below.

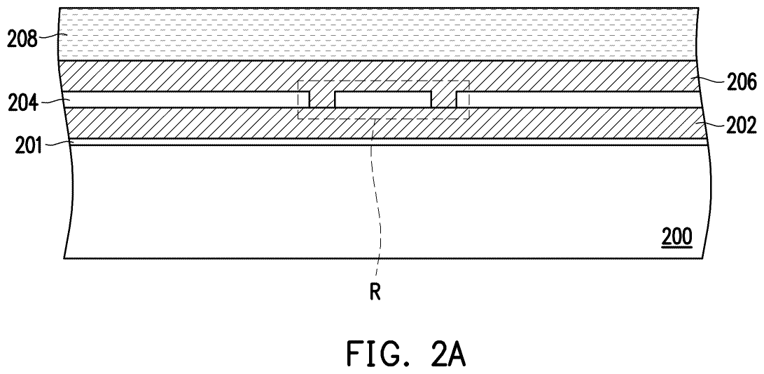

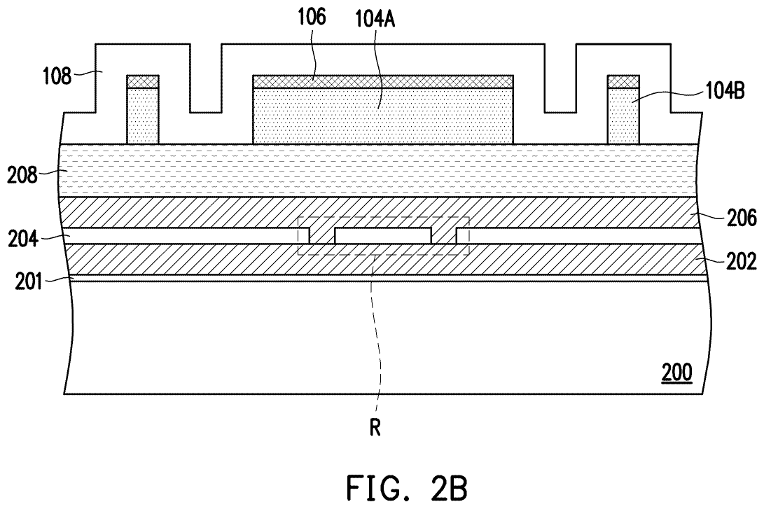

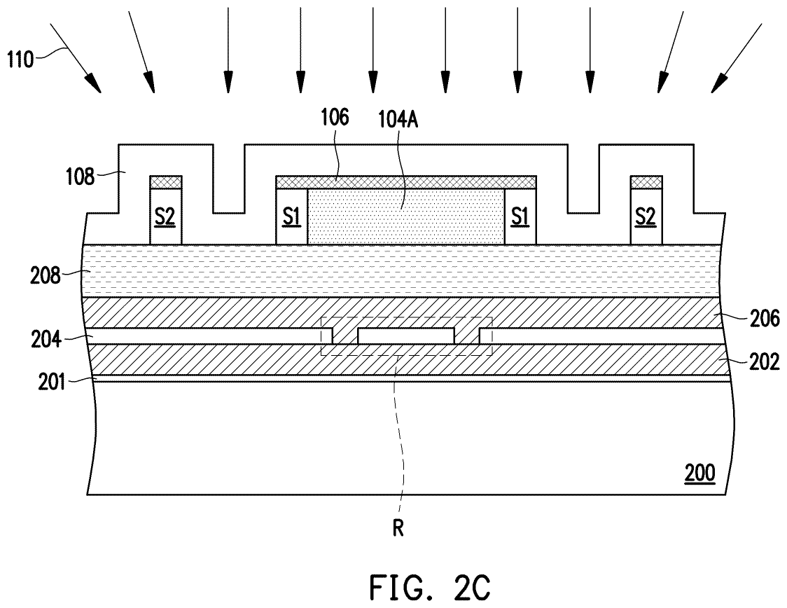

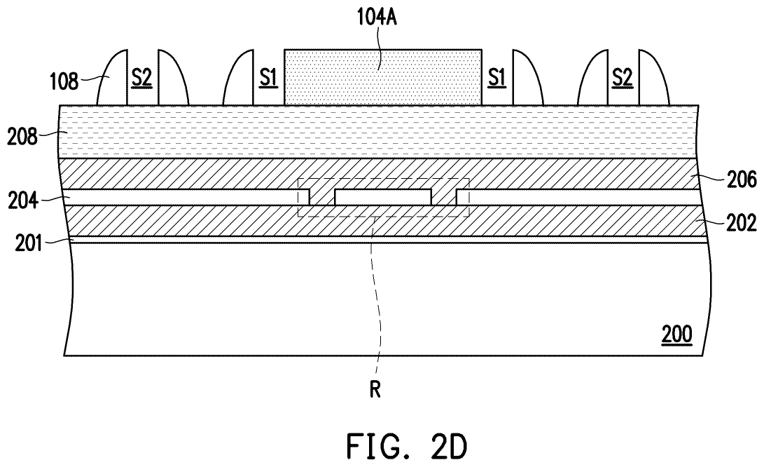

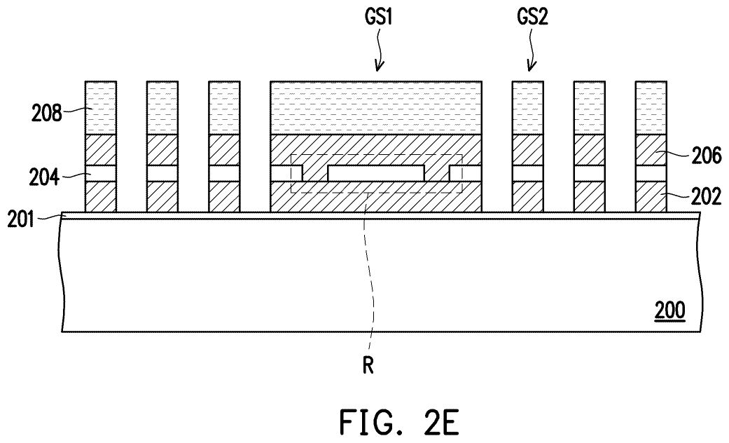

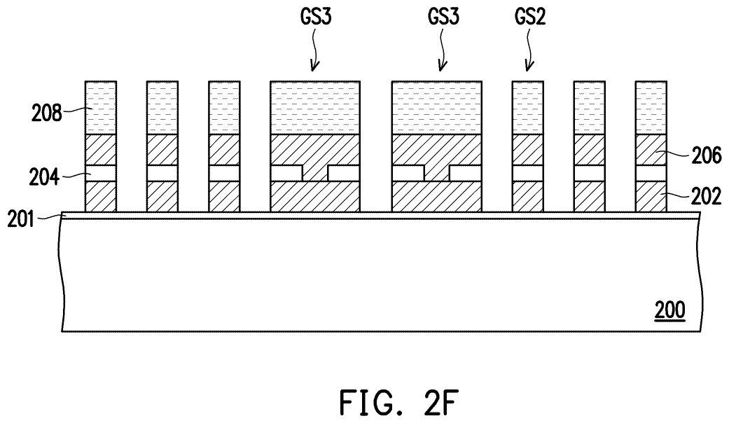

FIGS. 2A to 2F are schematic cross-sectional views of the manufacturing method of the gate structure according to the embodiment of the present invention. In the present embodiment, the same devices as those in the above embodiment are denoted by the same reference symbols and will not be described again.

Referring to FIG. 2A, a tunneling dielectric layer 201, a gate material layer 202, an inter-gate dielectric material layer 204, a gate material layer 206 and a hardmask material layer 208 are sequentially formed on a substrate 200. The substrate 200 is, for example, a silicon substrate. The tunneling dielectric layer 201 is, for example, a silicon oxide layer. The gate material layer 202 and the gate material layer 206 are, for example, polysilicon layers. The hardmask material layer 208 is, for example, a silicon nitride layer. In addition, the inter-gate dielectric material layer has a discontinuous region R. Therefore, in the discontinuous region R, the gate material layer 206 may pass through the tunneling dielectric layer 201 to contact the gate material layer 202.

Referring to FIG. 2B, the steps described in FIG. 1B are performed to form the first pattern 104A having a larger width, the plurality of second patterns 104B having a smaller width and the capping layer 106 on the hardmask material layer 208. Depending on the actual situation, in other embodiments, the capping layer 106 may be omitted. In the present embodiment, the first pattern 104A is located above the discontinuous region R, and the first pattern 104A overlaps with the discontinuous region R. Thereafter, the sacrificial layer 108 is conformally formed on the hardmask material layer 208. In the present embodiment, since the width of the gate structure of the memory cell formed subsequently and the pitch between adjacent gate structures are the same, the thickness of the sacrificial layer 108 is the same as the width of the second pattern 104B.

Referring to FIG. 2C, the steps described in FIG. 1C are performed, and the ashing process 110 is performed to remove the second patterns 104B through the sacrificial layer 108, and to remove a portion of the first pattern 104A from the sidewall of the first pattern 104A, so that the first pattern 104A has a reduced width, and the spaces S1 and the spaces S2 are formed. In this step, after removing a portion of the first pattern 104A from the sidewall of the first pattern 104A, the first pattern 104A may still overlap with the discontinuous region R.

Referring to FIG. 2D, as the step described in FIG. 1D, an anisotropic etching process is performed on the sacrificial layer 108 to remove a portion of the sacrificial layer 108 to form spacers formed by the sacrificial layer 108. In this step, the capping layer 106 is removed at the same time, and the space S1 and the spaces S2 are exposed.

Referring to FIG. 2E, as the step described in FIG. 1E, an anisotropic etching process is performed to remove a portion of the hardmask material layer 208, a portion of the gate material layer 206, a portion of the inter-gate dielectric material layer 204 and a portion of the gate material layer 202, so as to form a gate structure GS1 and a plurality of gate structures GS2 on the tunneling dielectric layer 201. Thereafter, as the step described in FIG. 1F, the first pattern 104A on the gate structure GS1 and the sacrificial layer 108 on the gate structures GS2 are removed.

In the way, the gate structure GS1 with a larger width includes the gate material layer 202, the inter-gate dielectric material layer 204 having the discontinuous region R, the gate material layer 206 and the hardmask material layer 208, and the gate structure GS2 with a smaller width includes the gate material layer 202, the continuous inter-gate dielectric material layer 204, the gate material layer 206 and the hardmask material layer 208.

In the present embodiment, the pitch between the gate structure GS1 and the gate structure GS2 corresponds to the width of the space S1. Therefore, the width of space S1 may be controlled by adjusting the time of the ashing process 110, thereby controlling the pitch between the gate structure GS1 and the gate structure GS2. In addition, the pitch between adjacent gate structures GS2 corresponds to the width of the second pattern 104B, so the pitch between adjacent gate structures GS2 may be controlled by adjusting the width of the second pattern 104B. In addition, the width of the gate structure GS2 corresponds to the width (thickness) of the spacer formed by the sacrificial layer 108, so the width of the gate structure GS2 may be controlled by adjusting the thickness of the sacrificial layer 108.

Referring to FIG. 2F, a patterning process is performed on the gate structure GS1 to form a pair of gate structures GS3, and each gate structure GS3 includes the discontinuous inter-gate dielectric material layer 204. In addition, the width of the gate structure GS3 is greater than the width of the gate structure GS2. In this way, the gate structures of the memory device of the present embodiment are formed.

The gate structures of the memory device of the present embodiment includes the gate structure GS3 having a larger width and the gate structures GS2 each having a smaller width. The gate structure GS2 located on the tunneling dielectric layer 201 may be used as the gate structure of the memory cell. Therefore, the gate structure GS2 includes a floating gate formed by the gate material layer 202, an inter-gate dielectric layer formed by the inter-gate dielectric material layer 204, a control gate formed by the gate material layer 206 and a hardmask layer formed by the hardmask material layer 208. In addition, the gate structure GS3 on the tunneling dielectric layer 201 may be used as a select gate structure, and thus the gate structure GS3 includes a select gate formed by the gate material layer 202 and the gate material layer 206 connected to each other, and a hardmask layer formed by the hardmask material layer 208. In addition, the tunneling dielectric layer 201 below the gate structure GS3 may be used as a gate dielectric layer.

In the present embodiment, after the patterned mask layer 104 is formed by a lithographic process and an etching process, an ashing process is performed to reduce the width of the first pattern 104A and remove the second patterns 104B to form the first pattern 104A with a desired width. In this way, by using the first pattern 104A as the etching mask and the subsequent patterning process, the gate structure GS3 having a desired width may be formed without being limited by the resolution of the lithography apparatus. In addition, by controlling the process parameters, for example, the ashing time, of the ashing process 110, the width of the gate structure GS3 formed subsequently and the pitch between the gate structure GS3 and the gate structure GS2 may be further controlled.

Furthermore, in the present embodiment, by adjusting the number of the second patterns 104B, a desired number of the gate structures GS2 may be formed. Therefore, when the size of the device continues to decrease, more gate structures GS2 may be formed without being limited by the resolution of the lithography apparatus, so that more gate structures GS2 adjacent to the gate structure GS3 may be used as dummy memory cells.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A patterning process, comprising:
forming a target layer on a substrate;
forming a patterned mask layer on the target layer, wherein the patterned mask layer comprises a first pattern and a second pattern, and a width of the first pattern is greater than a width of the second pattern;
conformally forming a sacrificial layer on the target layer;
performing an ashing process to remove the second pattern and remove a portion of the first pattern at least from a sidewall of the first pattern through the sacrificial layer so that the first pattern has a reduced width;
performing an anisotropic etching process to remove a portion of the sacrificial layer and a portion of the target layer; and
removing a remaining portion of the sacrificial layer and the first pattern.

2. The patterning process of claim 1, wherein a material of the patterned mask layer comprises carbon or a carbon-containing material.

3. The patterning process of claim 2, wherein the ashing process is performed using an oxygen plasma.

4. The patterning process of claim 1, wherein a thickness of the sacrificial layer is the same as the width of the second pattern.

5. The patterning process of claim 1, wherein after the anisotropic etching process is performed, the target layer comprises a first target pattern and a second target pattern, and a width of the first target pattern is greater than a width of the second target pattern.

6. The patterning process of claim 1, wherein the anisotropic etching process comprises:
performing a first anisotropic etching process on the sacrificial layer to form spacers; and
performing a second anisotropic etching process by using the spacers and the first pattern as an etching mask.

7. A manufacturing method of a gate structure of a memory device, comprising:
forming a tunneling dielectric layer on a substrate;
forming a first gate material layer on the tunneling dielectric layer;
forming an inter-gate dielectric material layer on the first gate material layer, wherein the inter-gate dielectric material layer has a discontinuous region;
forming a second gate material layer on the inter-gate dielectric material layer;
forming a hardmask material layer on the second gate material layer;
forming a patterned mask layer on the hardmask material layer, wherein the patterned mask layer comprises a first pattern and a plurality of second patterns, the first pattern is located above the discontinuous region, and a width of the first pattern is greater than a width of the second pattern;
conformally forming a sacrificial layer on the patterned mask layer;
performing an ashing process to remove the second pattern through the sacrificial layer and remove a portion of the first pattern at least from a sidewall of the first pattern so that the first pattern has a reduced width;
performing an anisotropic etching process to remove a portion of the sacrificial layer, a portion of the hardmask material layer, a portion of the second gate material layer, a portion of the inter-gate dielectric material layer and a portion of the first gate material layer; and
removing a remaining portion of the sacrificial layer and the first pattern.

8. The manufacturing method of claim 7, wherein a material of the patterned mask layer comprises carbon or a carbon-containing material.

9. The manufacturing method of claim 8, wherein the ashing process is performed using an oxygen plasma.

10. The manufacturing method of claim 7, wherein a thickness of the sacrificial layer is the same as the width of the second pattern.

11. The manufacturing method of claim 7, wherein after the anisotropic etching process is performed, a first gate structure and a plurality of second gate structures are formed on the substrate, and a width of the first gate structure is greater than a width of the second gate structure.

12. The manufacturing method of claim 11, wherein the second gate structure comprises a floating gate formed by the first gate material layer, an inter-gate dielectric layer formed by the inter-gate dielectric material layer, a control gate formed by the second gate material layer, and a hardmask layer formed by the hardmask material layer, which are sequentially formed on the tunneling dielectric layer.

13. The manufacturing method of claim 11, further comprising patterning the first gate structure to form a pair of third gate structures, wherein the inter-gate dielectric material layer in the third gate structure does not completely separate the first gate material layer from the second gate material layer.

14. The manufacturing method of claim 7, wherein the anisotropic etching process comprising:
performing a first anisotropic etching process on the sacrificial layer to form spacers; and
performing a second anisotropic etching process by using the spacers and the first pattern as an etching mask.
